(19) United States
(12) Patent Application Publication
(10) Pub. No.: US 2020/0174543 A1
(43) Pub. Date: Jun. 4, 2020

(54) OVERHEATING PROTECTION METHOD AND DEVICE OF USER EQUIPMENT, USER EQUIPMENT AND BASE STATION

(71) Applicant: Beijing Xiaomi Mobile Software Co., Ltd., Beijing (CN)

(72) Inventor: Wei HONG, Beijing (CN)

(21) Appl. No.: 16/780,285

(22) Filed: Feb. 3, 2020

Related U.S. Application Data
(63) Continuation of application No. PCT/CN2017/096673, filed on Aug. 9, 2017.

(51) Int. Cl. G06F 1/3209; H04W 24/08; H04M 1/725; H05K 10/00; H04W 8/24

(52) U.S. Cl. CPC G06F 1/3209; H04W 24/08; H04M 2250/12; H05K 10/00; H04W 8/24; H04M 1/72519

(57) ABSTRACT

A user equipment (UE) overheating protection method includes: in response to determining that UE is experiencing an overheating condition, sending, to a base station, first signaling to request a cooling configuration, and starting a timer of a preset timing period, wherein the first signaling includes assistance information signaling to a base station to solve the overheating condition, and the assistance information includes at least one of temporary capability of the UE or a target radio link configuration to which the UE is to be adjusted.

### CROSS-REFERENCE TO RELATED APPLICATIONS

This application is a continuation of International Application No. PCT/CN2017/096673, filed on Aug. 9, 2017, the entire contents of which are incorporated herein by reference.

### TECHNICAL FIELD

The present disclosure relates to the field of wireless communication, and in particular to a user equipment (UE) overheating protection method and device, UE, and a base station.

### BACKGROUND

In a Long Term Evolution (LTE) system, a mode of wireless transmission such as high-order Multiple-Input Multiple-Output (MIMO), multi-carrier aggregation, high-order modulation decoding, etc., may be set for UE to meet a demand of a user for high-speed data transmission. However, such a mode of high-speed wireless transmission may cause UE to overheat. UE overheating may further cause interruption of transmission of service data of the UE, and even restart of the UE, etc.

In related art, to ensure good experience of a user when using UE, a UE provider may generally control a temperature of the UE, such as by lowering a radio link configuration by detachment and re-attachment of the UE, to avoid an overheating condition of the UE. In related art, detachment and re-attachment of UE may interrupt transmission of service data, which lowers use experience of the user.

### SUMMARY

Embodiments of the present disclosure provide a UE overheating protection method and device, UE, and a base station, capable of cooling overheating UE by sending, to a base station, signaling to request a cooling configuration without interrupting transmission of service data, and avoiding a burden of frequent signaling at an arbitrary time by performing an overheating protection operation after a preset period after first signaling is sent as determined using a timer.

According to a first aspect of embodiments of the present disclosure, a user equipment (UE) overheating protection method performed by UE includes: in response to determining that the UE is experiencing an overheating condition, sending, to a base station, first signaling to request a cooling configuration, and starting a timer of a preset timing period; wherein the first signaling includes assistance information signaling to the base station to solve the overheating condition, and the assistance information includes at least one of temporary capability of the UE or a target radio link configuration to which the UE is to be adjusted.

According to a second aspect of embodiments of the present disclosure, a user equipment (UE) overheating protection method performed by a base station includes: receiving first signaling sent by UE to request a cooling configuration, wherein the first signaling includes assistance information signaling to the base station to solve the overheating condition, and the assistance information includes at least one of temporary capability of the UE or a target radio link configuration to which the UE is to be adjusted; generating response signaling containing the cooling configuration based on the first signaling; and sending the response signaling.

According to a third aspect of embodiments of the present disclosure, user equipment (UE) includes a processor; and a memory storing an instruction executable by the processor. The processor is configured to: in response to determining that the LIE is experiencing an overheating condition, send, to a base station, first signaling to request a cooling configuration, and start a timer of a preset timing period; wherein the first signaling includes assistance information signaling to the base station to solve the overheating condition, and the assistance information includes at least one of temporary capability of the UE or a target radio link configuration to which the UE is to be adjusted.

According to a fourth aspect of embodiments of the present disclosure, a base station includes a processor; and a memory storing an instruction executable by the processor. The processor is configured to: receive first signaling sent by UE to request a cooling configuration wherein the first signaling includes assistance information signaling to the base station to solve the overheating condition, and the assistance information includes at least one of temporary capability of the UE or a target radio link configuration to which the UE is to be adjusted; generate response signaling containing the cooling configuration based on the first signaling; and send the response signaling.

According to a fifth aspect of embodiments of the present disclosure, a non-transitory computer-readable storage medium has stored thereon a computer instruction that, when executed by a processor of a device, causes the device to perform: in response to determining that user equipment (UE) is experiencing an overheating condition, sending, to a base station, first signaling to request a cooling configuration, and starting a timer of a preset timing period; wherein the first signaling includes assistance information signaling to the base station to solve the overheating condition, and the assistance information includes at least one of temporary capability of the UE or a target radio link configuration to which the UE is to be adjusted.

According to a sixth aspect of embodiments of the present disclosure, a non-transitory computer-readable storage medium has stored thereon a computer instruction that, when executed by a processor of a device, causes the device to perform: receive first signaling sent by user equipment (UE) to request a cooling configuration, wherein the first signaling includes assistance information signaling to the base station to solve the overheating condition, and the assistance information includes at least one of temporary capability of the UE or a target radio link configuration to which the UE is to be adjusted; generate response signaling containing the cooling configuration based on the first signaling; and sending the response signaling.

The technical solution provided by embodiments of the present disclosure includes beneficial effects as follows.

When UE determines that an overheating condition is caused such as by an overly high radio link configuration, the UE sends, to a base station, first signaling to request a cooling configuration, such that the overheating UE may lower its temperature by signaling to the base station to request the cooling configuration without interrupting transmission of service data. Moreover, a timer of a preset Liming period is started after the first signaling is sent. A temperature of the UE at expiration of the timer is detected. An operation corresponding to a result of the detection is performed, avoiding a burden of frequent signaling at an arbitrary time.

The above general description and elaboration below are but exemplary and explanatory, and do not limit the subject disclosure.

### BRIEF DESCRIPTION OF THE DRAWINGS

A drawing here is incorporated in the subject disclosure, constitutes part of the subject disclosure, illustrates embodiments according to the subject disclosure, and together with the subject disclosure, serves to explain the principle of the subject disclosure.

FIG. 1A is a flowchart of a UE overheating protection method according to an exemplary embodiment.

FIG. 1B is a diagram of a scene of a UE overheating protection method according to an exemplary embodiment.

FIG. 1C is a diagram of timing of a timer according to an exemplary embodiment.

FIG. 1D is a diagram of timing of a timer according to an exemplary embodiment.

FIG. 2 is a flowchart of a UE overheating protection method according to an exemplary embodiment.

FIG. 3 is a flowchart of a UE overheating protection method according to an exemplary embodiment.

FIG. 4 is a flowchart of a UE overheating protection method according to an exemplary embodiment.

FIG. 5 is a flowchart of implementing a UE overheating protection method by, interaction between a base station and UE according to an exemplary embodiment.

FIG. 6 is a block diagram of a UE overheating protection device according to an exemplary embodiment.

FIG. 7 is a block diagram of a UE overheating protection device according to an exemplary embodiment.

FIG. 8 is a block diagram of a UE overheating protection device according to an exemplary embodiment.

FIG. 9 is a block diagram of a UE overheating protection device according to an exemplary embodiment.

FIG. 10 is a block diagram of a UE overheating protection device according to an exemplary embodiment.

FIG. 11 is a block diagram of a UE overheating protection device according to an exemplary embodiment.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless indicated otherwise. Implementations set forth in the following exemplary embodiments do not represent all implementations in accordance with the present disclosure. Rather, they are merely examples of apparatuses and methods in accordance with certain aspects related to the disclosure, as recited in the appended claims.

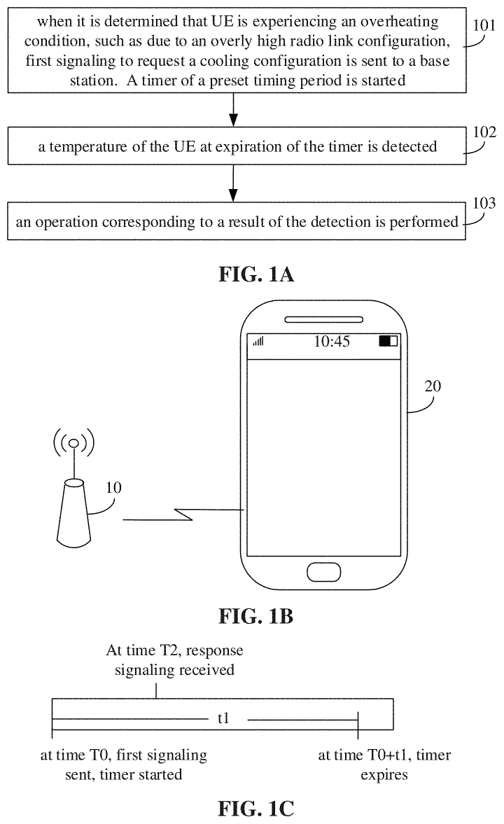

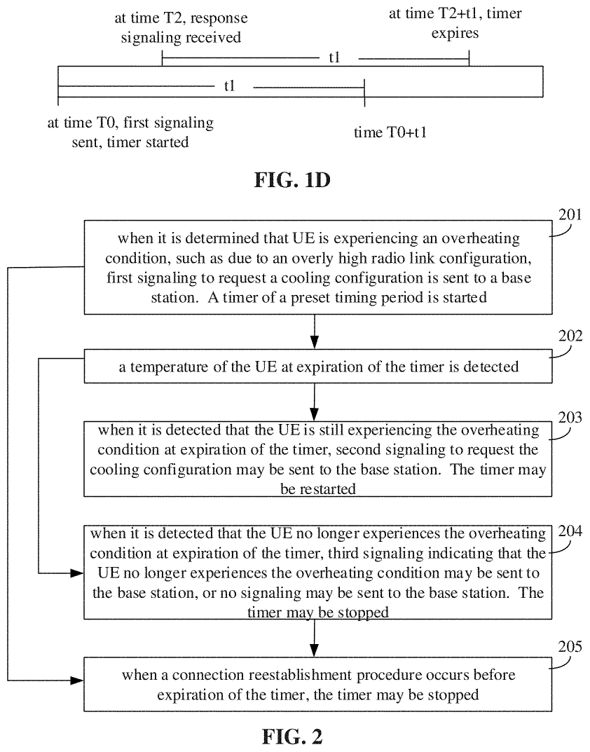

FIG. 1A is a flowchart of a user equipment (UE) overheating protection method according to an exemplary embodiment. FIG. 1B is a diagram of a scene of the UE overheating protection method according to an exemplary embodiment. FIG. 1C is a diagram of timing of a timer according to an exemplary embodiment. FIG. 1D is a diagram of timing of a timer according to an exemplary embodiment. The UE overheating protection method may apply to UE. As shown in FIG. 1A, the UE overheating protection method may include steps 101-103.

In step 101, when it is determined that the UE is experiencing an overheating condition, such as due to an overly high radio link configuration, first signaling to request a cooling configuration is sent to a base station. A timer of a preset timing period is started.

In an embodiment, the timer of the preset timing period may be started while sending the first signaling. The timer may be started as soon as the first signaling is sent.

In an embodiment, the timer of the preset timing period may be set by the base station. The set timer may be indicated to the UE by Radio Resource Control (RRC) signaling, such as Otherconfig signaling in an RRC connection reconfiguration message.

In an embodiment, the first signaling may include assistance information that facilitates solving the overheating condition of the UE by the base station. The first signaling may carry assistance information, signaling to the base station to solve the overheating condition of the UE. For example, the assistance information may include information indicating lower-performance caused by the overheating condition. Also for example, the assistance information may include a target radio link configuration to which the UE is to be adjusted. As another example, the assistance information may include temporary capability of the UE. Temporary capability of UE may be represented by a type of UE or a radio frequency parameter.

In an embodiment, it may be determined whether the UE is experiencing an overheating condition by determining whether a temperature of the UE is greater than a preset temperature threshold for a set period of time. For example, when the temperature of the UE is greater than 85 degrees for 5 minutes, it may be determined that the UE is experiencing an overheating condition. In an embodiment, the temperature of the UE may be a temperature of a surface of a battery of the UE. In art embodiment, the temperature of the UE may be a temperature of a surface of a Central Processing Unit (CPU) of the UE. In an embodiment, the temperature of the UE may be a temperature of a front screen or a rear housing of the UE, etc.

In step 102, a temperature of the UE at expiration of the timer is detected.

In an embodiment, referring to FIG. 1C, the UE may send the first signaling time T0. The timer may be started at time T0. The timing period of the timer may be t1. Then, the UE may detect the temperature of the UE at time T0+t1. The UE may receive, at time T2, response signaling that is fed hack according to the first signaling by the base station and contains the cooling configuration. Time T2 may be time between time T0 and time T0+t1. No operation may be performed on the timer. The temperature of the UE at time T0+t1 may be detected.

In an embodiment, the timer may be reset if the response signaling is received before expiration of the timer. The response signaling may be fed back by the base station based on the first signaling. The response signaling may contain the cooling configuration. After the timer is reset, the temperature of the UE at expiration of the timer may be detected. Referring to FIG. 1D, the UE may send the first signaling at time T0. The timer may be started at time T0. The timing period of the timer may be t1. Then, the UE may detect the temperature of the UE at time T0−t1. The UE may receive, at time T2, response signaling that is fed back by the base station and contains the cooling configuration. Time T2 may be time between time T0 and time T0+t1. The timer may be reset, namely restarted, at time T2. The UE may detect the temperature of the UE at time T2+t1.

In an embodiment, if the UE starts a connection reestablishment procedure before expiration of the timer, the timer may be stopped.

In step 103, an operation corresponding to a result of the detection is performed.

In an embodiment, the result of the detection may indicate that the UE is still experiencing the overheating condition. The result of the detection may indicate that the UE no longer experiences the overheating condition.

An exemplary scene as shown in FIG. 1B may include a base station 10, and UE 20 such as a smart phone, a tablet computer, etc. When it is determined that an overheating condition is caused by an overly high radio link configuration, the UE 20 may send first signaling to the base station 10 to request a cooling configuration. Thus, the overheating UE 20 may lower its temperature by signaling to the base station 10 to request a cooling configuration. Moreover, a timer of a preset timing period may be set after the first signaling is sent. A temperature of the UE 20 at expiration of the timer may be detected. An operation corresponding to a result of the detection may be performed. For example, if it is detected that the UE 20 is still experiencing the overheating condition, the signaling for requesting the cooling configuration may be sent to the base station 10 again. In addition, the timer may be restarted.

In the above embodiments, overheating LTE may lower its temperature by signaling a base station to request a cooling configuration without interrupting transmission of service data. Moreover, a timer of a preset timing period is started after the first signaling is sent. A temperature of the UE at expiration of the timer is detected. An operation corresponding to a result of the detection is performed, avoiding a burden of frequent signaling at an arbitrary time.

In an embodiment, the temperature of the UE at expiration of the timer may be detected as follows. The timer may be reset when the response signaling is received before expiration of the timer. The response signaling may be fed back by the base station based on the first signaling. The response signaling may contain the cooling configuration. After the timer is reset, the temperature of the UE at expiration of the timer may be detected.

In an embodiment, the operation corresponding to the result of the detection may be performed as follows. When it is detected that the UE is still experiencing the overheating condition at expiration of the timer, second signaling to request the cooling configuration may be sent to the base station. The timer may be restarted.

In an embodiment, the operation corresponding to the result of the detection may be performed as follows. When it is detected that the UE no longer experiences the overheating condition at expiration of the timer, third signaling indicating that the UE no longer experiences the overheating condition may be sent to the base station. The timer may be stopped. Alternatively, no signaling may be sent to the base station. The timer may be stopped.

In an embodiment, the UE overheating protection method may further include a step as follows. When a connection reestablishment procedure occurs before expiration of the timer, the timer may be stopped.

FIG. 2 is a flowchart of a LTE overheating protection method according to an exemplary embodiment. As shown in FIG. 2, the method may include the following steps.

In step 201, when it is determined that UE is experiencing an overheating condition, such as due to an overly high radio link configuration, first signaling to request a cooling configuration is sent to a base station, and a timer of a preset timing period is started, similar to step 101 (FIG. 1A).

In step 202, a temperature of the UE at expiration of the timer is detected, similar to step 102 (FIG. 1A).

In step 203, when it is detected that the UE is still experiencing the overheating condition at expiration of the timer, second signaling to request the cooling configuration may be sent to the base station. The timer may be restarted.

In an embodiment, the first signaling and the second signaling may be identical. For example, assistance information that facilitates solving the overheating condition of the UE by the base station included in the first signaling may be identical to that included in the second signaling. The first signaling and the second signaling may differ. For example, assistance information that facilitates solving the overheating condition of the UE by the base station included in the first signaling may differ from that included in the second signaling.

In step 204, when it is detected that the UE no longer experiences the overheating condition at expiration of the timer, third signaling indicating that the UE no longer experiences the overheating condition may be sent to the base station, or no signaling may be sent to the base station. The timer may be stopped.

In an embodiment, when the result of the detection indicates that the UE no longer experiences the overheating condition, the third signaling configured to indicate that the UE no longer experiences the overheating condition may be sent to the base station based on a system setting, or no signaling is sent to the base station.

In step 205, when a connection reestablishment procedure occurs before expiration of the timer, the timer may be stopped.

In an embodiment, if the UE connection reestablishment procedure occurs before expiration of the timer due to a poor communication signal, etc., the timer may be stopped.

In the above embodiment, overheating UE may determine, based on a timer of a preset timing period, an interval for sending signaling to request a cooling configuration, avoiding a burden of frequent signaling to a base station at an arbitrary time, reducing utilization of a spectrum resource and a signaling burden on a network.

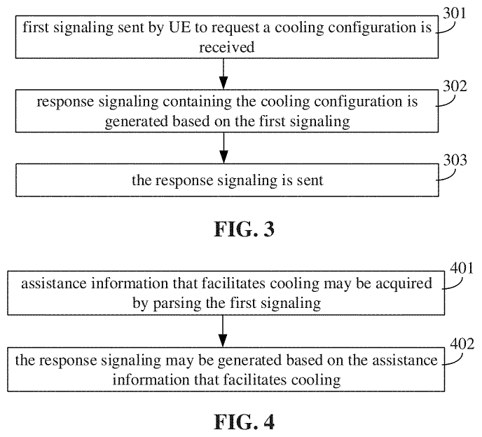

FIG. 3 is a flowchart of a UE overheating protection method according to an exemplary embodiment. The UE overheating protection method may apply to a base station. As shown in FIG. 3, the UE overheating protection method may include steps 301-303.

In step 301, first signaling sent by UE to request a cooling configuration is received.

In an embodiment, the first signaling may include assistance information that facilitates solving the overheating condition of the UE by the base station. The first signaling may carry assistance information, signaling to the base station to solve the overheating condition of the UE. For example, the assistance information may include information indicating lower-performance caused by the overheating condition. Also for example, the assistance information may include a target radio link configuration to which the UE is to be adjusted. As another example, the assistance information may include temporary capability of the UE. Temporary capability of UE may be represented by a type of UE or a radio frequency parameter.

In step 302, response signaling containing the cooling configuration is generated based on the first signaling.

In an embodiment, the response signaling may be an RRC connection reconfiguration message.

In an embodiment, the first signaling may include a target radio link configuration to which the UE is to be adjusted. The base station may generate response signaling directly based on the target radio link configuration to which the UE is to be adjusted.

In an embodiment, the first signaling may include temporary capability of the UE. The base station may determine the target radio link configuration to which the UE is to be adjusted according to the temporary capability of the UE. The temporary capability of the UE may be determined such as according to the type of the UE in the first signaling. The base station may then generate the response signaling.

In step 303, the response signaling is sent.

An exemplary scene as shown in FIG. 1B may include a base station 10, and UE 20 such as a smart phone, a tablet computer, etc. When it is determined that an overheating condition is caused by an overly high radio link configuration, the UE 20 may send first signaling to the base station 10 to request a cooling configuration. Thus, the overheated UE 20 may lower its temperature by signaling to the base station 10 to request a cooling configuration. Moreover, a timer of a preset timing period may be set after the first signaling is sent. A temperature of the UE 20 at expiration of the timer may be detected. An operation corresponding to a result of the detection may be performed. For example, if it is detected that the UE is still experiencing the overheating condition, the base station 10 may be signaled again to request the cooling configuration. In addition, the tuner may be restarted.

In the above embodiment, the base station may determine a target radio link configuration to which the UE is to be adjusted based on first signaling sent by the UE to request a cooling configuration. The UE is cooled by lowering the radio link configuration of the UE, avoiding interruption of transmission of service data.

In an embodiment, response signaling containing the cooling configuration may be generated based on the first signaling as follows. The assistance information that facilitates cooling may be acquired by parsing the first signaling. The response signaling may be generated based on the assistance information that facilitates cooling.

FIG. 4 is a flowchart of a UE overheating protection method according to an exemplary embodiment. As shown in FIG. 4, the method may include the following steps.

In step 401, assistance information that facilitates cooling may be acquired by parsing the first signaling.

In an embodiment, the assistance information may include information indicating lower-performance caused by the overheating condition. The assistance information may include a target radio link configuration to which the UE is to be adjusted. The assistance information may include temporary capability of the UE. Temporary capability of UE may be represented by a type of UE or a radio frequency parameter.

In step 402, the response signaling may be generated based on the assistance information that facilitates cooling.

In an embodiment, the first signaling may include a target radio link configuration to which the UE is to be adjusted. The base station may generate response signaling directly based on the target radio link configuration to which the UE is to be adjusted.

In an embodiment, the first signaling may include temporary capability of the UE. The base station may determine the target radio link configuration to which the UE is to be adjusted according to the temporary capability of the UE. In an embodiment, the temporary capability of the UE may be determined such as according to the type of the UE in the first signaling. The base station may then generate the response signaling. The temporary capability of the UE may be represented by the type of UE. The base station may then determine the target radio link configuration to which the UE is to be adjusted according to the type of UE in the first signaling. In an embodiment, the temporary capability of the UE may be represented by a radio frequency parameter in the first signaling. The base station may then determine the temporary capability of the UE according to the radio frequency parameter in the first signaling.

In an embodiment, the base station may generate response signaling of RRC connection reconfiguration based on the determined target radio link configuration to which the UE is to be adjusted.

In the above embodiment, the base station may determine a target radio link configuration to which the UE is to be adjusted based on first signaling sent by the UE to request a cooling configuration. The UE is cooled by lowering the radio link configuration of the UE.

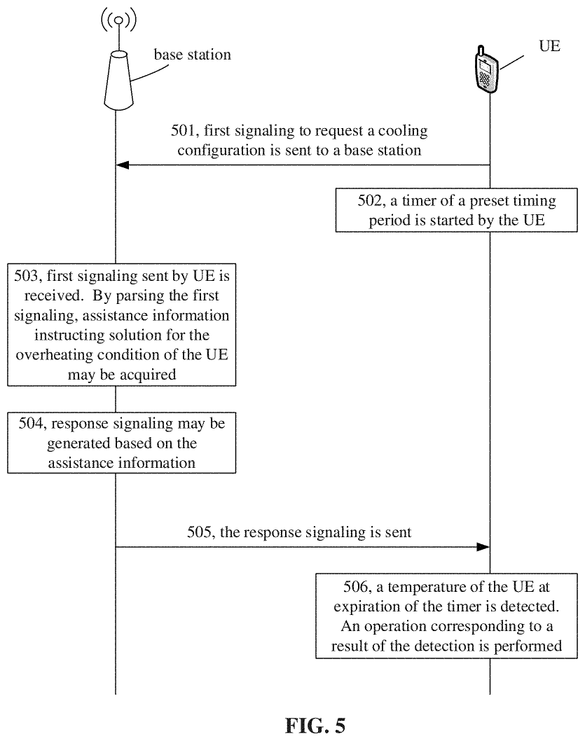

FIG. 5 is a flowchart of implementing a UE overheating protection method by interaction between a base station and UE according to an exemplary embodiment. As shown in FIG. 5, the method may include the following steps.

In step 501, the UE sends, to a base station, first signaling to request a cooling configuration when the UE is experiencing an overheating condition due to an overly high radio link configuration.

In step 502, a timer of a preset timing period is started by the UE.

In an embodiment, the timer of the preset timing period may be started after the first signaling is sent. The timer may be started as soon as the first signaling is sent.

In step 503, the base station receives the first signaling sent by the UE. By parsing the first signaling, the base station may acquire assistance information that instructs a solution for the overheating condition of the UE.

In step 504, the base station may generate response signaling based on the assistance information.

In step 505, the base station sends the response signaling.

In step 506, a temperature of the UE at expiration of the timer is detected. An operation corresponding to a result of the detection is performed.

In the above embodiment, the overheating UE may lower its temperature by signaling to a base station to request a cooling configuration without interrupting transmission of service data, avoiding a burden of frequent signaling at an arbitrary time by performing an overheating protection operation after a preset period after first signaling is sent as determined using a timer.

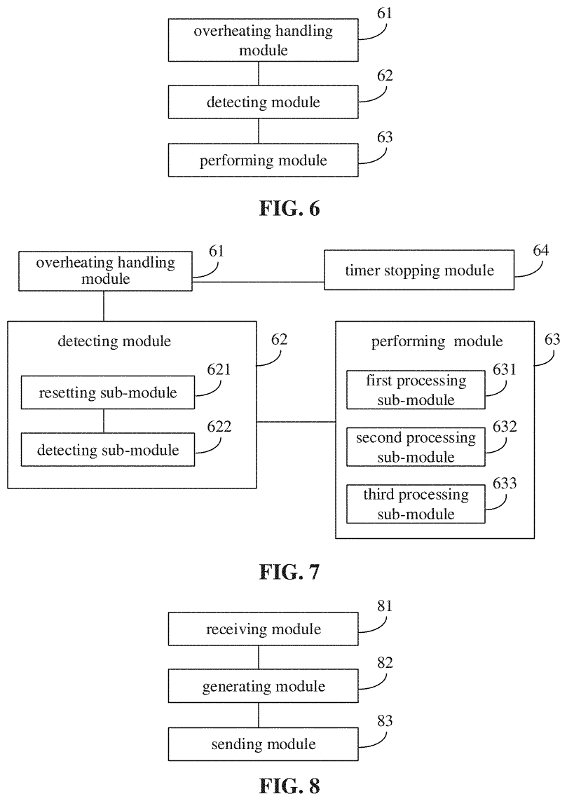

FIG. 6 is a block diagram of a UE overheating protection device according to an exemplary embodiment. The device applies to UE, As shown in FIG. 6, the UE overheating protection device includes an overheating handling module 61, a detecting module 62, and a performing module 63.

The overheating handling module 61 is configured to, in response to determining that the UE is experiencing an overheating condition due to an overly high radio link configuration, send, to a base station, first signaling to request a cooling configuration, and start a timer of a preset timing period.

The detecting module 62 is configured to detect a temperature of the UE at expiration of the timer.

The performing module 63 is configured to perform an operation corresponding to a result of the detection.

FIG. 7 is a block diagram of a LIE overheating protection device according to an exemplary embodiment. As shown in FIG. 7, based on the embodiment shown in FIG. 6, in an embodiment, the detecting module 62 may include a resetting sub-module 621 and a detecting sub-module 622.

The resetting sub-module 621 may be configured to reset the timer in response to receiving, before expiration of the timer, response signaling that is fed back by the base station based on the first signaling and that contains the cooling configuration.

The detecting sub-module 622 may be configured to, after the timer is reset, detect the temperature of the UE at expiration of the timer.

In an embodiment, the performing module 63 may include a first processing sub-module 631. The first processing sub-module 631 may be configured to, in response to the result of the detection being that the UE is still experiencing the overheating condition at expiration of the timer, send, to the base station, second signaling to request the cooling configuration, and restarting the timer.

In an embodiment, the performing module 63 may include a second processing sub-module 632 or a third processing sub-module 633. The second processing sub-module 632 may be configured to, in response to the result of the detection being that the UE no longer experiences the overheating condition at expiration of the timer, send, to the base station, third signaling indicating that the UE no longer experiences the overheating condition, and stopping the timer. The third processing sub-module 633 may be configured to send no signaling to the base station, and stopping the timer.

In an embodiment, the device may further include a timer stopping module 64. The timer stopping module 64 may be configured to, in response to occurrence of a connection reestablishment procedure before expiration of the tuner, stop the tuner.

FIG. 8 is a block diagram of a UE overheating protection device according to an exemplary embodiment. The device applies to a base station. As shown in FIG. 8, the UE overheating protection device includes a receiving module 81, a generating module 82, and a sending module 83.

The receiving module 81 is configured to receive first signaling sent by UE to request a cooling configuration.

The generating module 82 is configured to generate response signaling containing the cooling configuration based on the first signaling received by the receiving module 81.

The sending module 83 is configured to send the response signaling generated by the generating module 82.

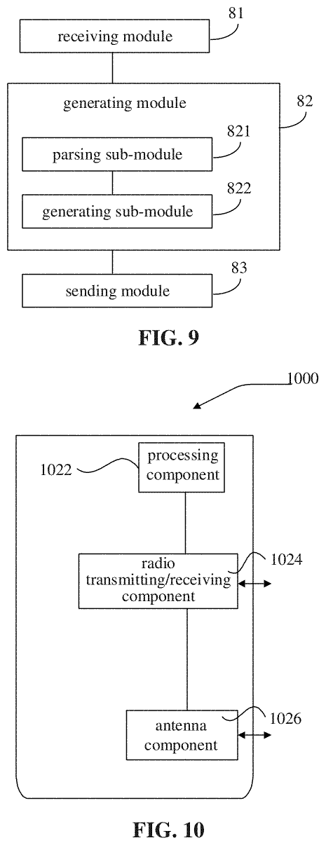

FIG. 9 is a block diagram of a UE overheating protection device according to an exemplary embodiment. As shown in FIG. 9, based on the embodiment shown in FIG. 8, in an embodiment, the generating module 82 may include a parsing sub-module 821 and a generating sub-module 822. The parsing sub-module 821 may be configured to acquire assistance information that facilitates cooling by parsing the first signaling. The generating sub-module 822 may be configured to generate the response signaling based on the assistance information that facilitates cooling.

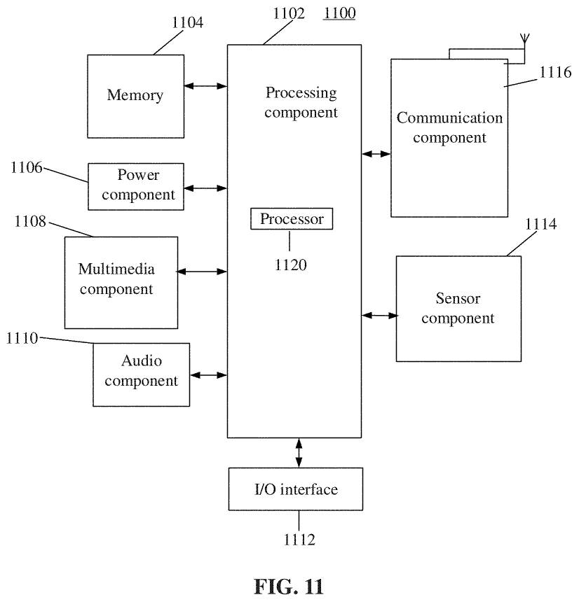

FIG. 10 is a block diagram of a UE overheating protection device 1000 according to an exemplary embodiment. The device 1000 may be provided as a base station. Referring to FIG. 10, the device 1000 includes a processing component 1022, a radio transmitting/receiving component 1024, an antenna component 1026, and a signal processing part dedicated to a radio interface. The processing component 1022 may further include one or more processors. A processor of the processing component 1022 may be configured to perform the above described UE overheating protection methods.

In an exemplary embodiment, a non-transitory computer-readable storage medium including instructions is provided. The instructions may be executed by the processing component 1022 of the device 1000 to perform the above described UE overheating protection methods. For example, the non-transitory computer-readable storage medium may be a Read-Only Memory (ROM), a Random Access Memory (RAM), a Compact Disc Read-Only Memory (CD-ROM), a magnetic tape, a floppy disk, optical data storage equipment, etc.

In an exemplary embodiment, a non-transitory computer-readable storage medium has stored thereon instructions. When executed by a processor of a base station, the instructions cause the base station to perform the UE overheating protection method as disclosed in the second aspect, including: receiving first signaling sent by UE to request a cooling configuration; generating response signaling containing the cooling configuration based on the first signaling; and sending the response signaling.

FIG. 11 is a block diagram of a UE overheating protection device 1100 according to an exemplary embodiment. For example, the device 1100 may be user equipment, such as a smart phone.

Referring to FIG. 11, the device 1100 may include one or more of a processing component 1102, memory 1104, a power supply component 1106, a multimedia component 1108, an audio component 1110, an Input/Output (I/O) interface 1112, a sensor component 1114, and a communication component 1116.

The processing component 1102 may generally control an overall operation of the device 1100, such as operations associated with display, a telephone call, data communication, a camera operation, and a recording operation. The processing component 1102 may include one or more processors 1120 to execute instructions so as to complete all or some steps of the above described methods. In addition, the processing component 1102 may include one or more modules to facilitate interaction between the processing component 1102 and other components. For example, the processing component 1102 may include a multimedia module to facilitate interaction between the multimedia component 1108 and the processing component 1102.

The memory 1104 may be configured to store various types of data to support the operation at the device 1100. Examples of such data may include instructions of any application configured to operate on the device 1100, messages, pictures, and/or the like. The memory 1104 may be realized by any type of transitory or non-transitory storage equipment or combination thereof, such as Static Random Access Memory (SRAM), Electrically Erasable Programmable Read-Only Memory (EEPROM), Erasable Programmable Read-Only Memory (EPROM), Programmable Read-Only Memory (PROM), Read-Only Memory (ROM), magnetic memory, flash memory, a magnetic disk, or a compact disk.

The power supply component 1106 may supply electric power to various components of the device 1100. The power supply component 1106 may include a power management system, one or more power sources, and other components related to generating, managing and distributing electricity for the device 1100.

The multimedia component 1108 may include a screen providing an output interface between the apparatus 1100 and a user. The screen may include a Liquid Crystal Display (LCD) and a Touch Panel (TP). If the screen includes a TP, the screen may be realized as a touch screen to receive an input signal from a user. The TP may include one or more touch sensors for sensing touch, slide and gestures on the TP. The touch sensors not only may sense the boundary of a touch or slide move, but also detect the duration and pressure related to the touch or slide move. The multimedia component 1108 may include a front camera and/or a rear camera. When the equipment 1100 is in an operation mode such as a shooting mode or a video mode, the front camera and/or the rear camera may receive external multimedia data. Each of the front camera or the rear camera may be a fixed optical lens system or may have a focal length and be capable of optical zooming.

The audio component 1110 may be configured to output and/or input an audio signal. For example, the audio component 1110 may include a microphone (MIC). When the device 1100 is in an operation mode such as a call mode, a recording mode, and a voice recognition mode, the MIC may be configured to receive an external audio signal. The received audio signal may be further stored in the memory 1104 or may be sent via the communication component 1116. The audio component 1110 may further include a loudspeaker configured to output the audio signal.

The I/O interface 1112 may provide an interface between the processing component 1102 and a peripheral interface module. Such a peripheral interface module may be a keypad, a click wheel, a button, and/or the like. Such a button may include but is not limited to: a homepage button, a volume button, a start button, and a lock button.

The sensor component 1114 may include one or more sensors for assessing various states of the device 1100. For example, the sensor component 1114 may detect an on/off state of the device 1100 and relative positioning of components such as the display and the keypad of the device 1100. The sensor component 1114 may further detect a change in the position of the device 1100 or of a component of the device 1100, whether there is contact between the device 1100 and a user, the orientation or acceleration/deceleration of the device 1100, a change in the temperature of the device 1100. The sensor component 1114 may include a proximity sensor configured to detect existence of a nearby object without physical contact. The sensor component 1114 may further include an optical sensor such as a Complementary Metal-Oxide-Semiconductor (CMOS) or a Charge-Coupled-Device (CCD) image sensor used in an imaging application. The sensor component 1114 may further include art acceleration sensor, a gyroscope sensor, a magnetic sensor, a distance sensor, a pressure sensor, or a temperature sensor.

The communication component 1116 may be configured to facilitate wired or wireless communication between the device 1100 and other equipment. The device 1100 may access a wireless network based on a communication standard such as Wi-Fi, 4G, 5G, or combination thereof. The communication component 1116 may broadcast related information or receive a broadcast signal from an external broadcast management system via a broadcast channel. The communication component 1116 may further include a Near Field Communication (NFC) module for short-range communication. The communication component 1116 may be based on technology such as Radio Frequency Identification (RFID), Infrared Data Association (IrDA), Ultra-Wideband (UWB) technology, Bluetooth (BT), etc.

The device 1100 may be realized by one or more electronic components such as an Application Specific Integrated Circuit (ASIC), a Digital Signal Processor (DSP), a Digital Signal Processing Device (DSPD), a Programmable Logic Device (PLD), a Field Programmable Gate Array (FPGA), a controller, a microcontroller, a microprocessor, etc., to implement the UE overheating protection method.

In an exemplary embodiment, a non-transitory computer-readable storage medium including instructions, such as the memory 1104 including instructions, may be provided. The instructions may be executed by the processor 1120 of the device 1100 to perform the above described methods. For example, the non-transitory computer-readable storage medium may be Read-Only Memory (ROM), Random Access Memory (RAM), Compact Disc Read-Only Memory (CD-ROM), a magnetic tape, a floppy disk, optical data storage equipment, and/or the like.

In an exemplary embodiment, a non-transitory computer-readable storage medium has stored thereon instructions. When executed by a processor of a device, the instructions cause the device to perform the UE overheating protection methods, including: in response to determining that UE is experiencing an overheating condition due to an overly high radio link configuration, sending, to a base station, first signaling to request a cooling configuration, and starting a timer of a preset timing period; detecting a temperature of the UE at expiration of the timer; and performing an operation corresponding to a result of the detection.

Other embodiments of the present disclosure will be apparent to one skilled in the art after considering the present disclosure. The present disclosure is intended to cover any variation, use, or adaptation of the present disclosure following the general principle thereof and including such departures from the present disclosure as come within known or customary practice in the art. The described embodiments are exemplary only, with a true scope and spirit of the disclosure being indicated by the appended claims.

The present disclosure is not limited to the exact construction that has been described above and illustrated in the accompanying drawings. Various modifications and changes can be made without departing from the scope of the present disclosure. It is intended that the scope of the present disclosure be limited only by the appended claims.

1. A user equipment (UE) overheating protection method performed by UE, the method comprising:
in response to determining that the UE is experiencing an overheating condition, sending, to a base station, first signaling to request a cooling configuration; and starting a timer of a preset timing period,
wherein the first signaling comprises assistance information signaling to the base station to solve the overheating condition, and the assistance information comprises at least one of temporary capability of the UE or a target radio link configuration to which the UE is to be adjusted.

2. The method of claim 1, wherein the temporary capability of the UE comprises a radio frequency parameter of the UE.

3. The method of claim 1, further comprising:
detecting a temperature of the UE at expiration of the timer.

4. The method of claim 1, further comprising detecting a temperature of the UE at expiration of the timer by:
resetting the timer in response to receiving, before expiration of the timer, response signaling, wherein the response signaling is fed back by the base station based on the first signaling and contains the cooling configuration; and
after the timer is reset, detecting the temperature of the UE at expiration of the timer.

5. The method of claim 1, further comprising performing an operation corresponding to a result of a detection by:
in response to the result of the detection being that the UE is still experiencing the overheating condition at expiration of the timer, sending, to the base station, second signaling to request the cooling co ration, and restarting the timer.

6. The method of claim 1, further comprising performing an operation corresponding to a result of a detection by one of:
in response to the result of the detection being that the UE no longer experiences the overheating condition at expiration of the timer, sending, to the base station, third signaling indicating that the UE no longer experiences the overheating condition, and stopping the timer; or
sending no signaling to the base station, and stopping the timer.

7. The method of claim 1, further comprising:
in response to occurrence of a connection reestablishment procedure before expiration of the timer, stopping the timer.

8. A user equipment (UE) overheating protection method performed by a base station, the method comprising:
receiving first signaling sent by UE to request a cooling configuration;
generating response signaling containing the cooling configuration based on the first signaling, wherein the first signaling comprises assistance information signaling to the base station to solve the overheating condition, and the assistance information comprises at least one of temporary capability of the UE or a target radio link configuration to which the UE is to be adjusted; and
sending the response signaling.

9. The method of claim 8, wherein the generating response signaling containing the cooling configuration based on the first signaling comprises:
acquiring assistance information that facilitates cooling by parsing the first signaling; and
generating the response signaling based on the assistance information that facilitates cooling.

10. User Equipment (UE), comprising:
a processor; and
a memory storing an instruction executable by the processor,
wherein the processor is configured to:
in response to determining that the UE is experiencing an overheating condition, send, to a base station, first signaling to request a cooling configuration, and start a timer of a preset timing period,
wherein the first signaling comprises assistance information signaling to the base station to solve the overheating condition, and the assistance information comprises at least one of temporary capability of the UE or a target radio link configuration to which the UE is to be adjusted.

11. The UE of claim 10, wherein the temporary capability of the UE comprises a radio frequency parameter of the UE.

12. The UE of claim 10, wherein the processor is further configured to:
detect a temperature of the UE at expiration of the timer.
